(19) United States
(12) Patent Application Publication
(10) Pub. No.: US 2024/0384412 A1
(43) Pub. Date: Nov. 21, 2024

(54) FILM-FORMING METHOD AND SUBSTRATE PROCESSING APPARATUS

(71) Applicant: Tokyo Electron Limited, Tokyo (JP)

(72) Inventor: Hiroki MURAKAMI, Yamanashi (JP)

(21) Appl. No.: 18/653,410

(22) Filed: May 2, 2024

(30) Foreign Application Priority Data
May 16, 2023 (JP) 2023-080854

(51) Int. Cl. C23C 16/455; C23C 16/44; C23C 16/458; C23C 16/52

(52) U.S. Cl. CPC C23C 16/45553; C23C 16/4408; C23C 16/45548; C23C 16/52

(57) ABSTRACT

A film-forming method for forming a film on a substrate by switching gas to be supplied to the substrate in a processing container, the film-forming method including supplying, in the processing container, dilution gas that is heated to a temperature that is higher than a temperature of the substrate, from a second injector that is different from a first injector when supplying one kind of gas from the first injector into the processing container.

### CROSS-REFERENCE TO RELATED APPLICATION

The present application is based upon and claims priority to Japanese Patent Application No. 2023-080854, filed on May 16, 2023, the entire contents of which are incorporated herein by reference.

### BACKGROUND OF THE INVENTION

### 1. Field of the Invention

The present disclosure relates to a film-forming method and a substrate processing apparatus.

### 2. Description of the Related Art

Patent Document 1 discloses a method for manufacturing a semiconductor device having a first gas supply step for supplying a raw material gas to a substrate housed in a processing chamber and a second gas supply step for supplying a reaction gas to the substrate, wherein the first gas supply step and the second gas supply step are alternately performed to form a film on the substrate, and wherein in the second gas supply step, the reaction gas is supplied from a reaction gas supply system for supplying the reaction gas to the substrate and an inert gas is supplied to the substrate from a supply system different from the reaction gas supply system so that the reaction gas can easily reach the center of the substrate.
Patent Document 1: WO2020/066800

### SUMMARY OF THE INVENTION

According to one aspect of the present invention, there is provided
a film-forming method for forming a film on a substrate by switching gas to be supplied to the substrate in a processing container, the film-forming method including:
supplying, in the processing container, dilution gas that is heated to a temperature that is higher than a temperature of the substrate, from a second injector that is different from a first injector when supplying one kind of gas from the first injector into the processing container.

### BRIEF DESCRIPTION OF THE DRAWINGS

FIG. 1 is a schematic diagram illustrating an example of the configuration of a substrate processing apparatus;

FIG. 2 is a cross-sectional view of an example of a configuration of a substrate processing apparatus;

FIG. 3 is a cross-sectional view illustrating an example of a gas supply pipe;

FIG. 4 is a schematic view illustrating another example of a configuration of a substrate processing apparatus;

FIGS. 5A and 5B are schematic views illustrating an example of a gas discharge direction;

FIGS. 6A and 6B are time charts illustrating an example of a film forming process;

FIG. 7 is an example of a graph illustrating a film thickness and in-plane uniformity;

FIGS. 8A to 8C are examples of a graph illustrating a film thickness distribution;

FIGS. 9A and 9B are time charts illustrating an example of a film forming process;

FIG. 10 is an example of a graph illustrating film thickness and in-plane uniformity; and

FIGS. 11A and 11B are examples of a graph illustrating film thickness distribution.

### DESCRIPTION OF THE EMBODIMENTS

Hereinafter, an embodiment for implementing the present disclosure will be described with reference to the drawings. In each drawing, the same elements are denoted by the same reference numerals, and overlapping descriptions may be omitted.

### [Substrate Processing Apparatus]

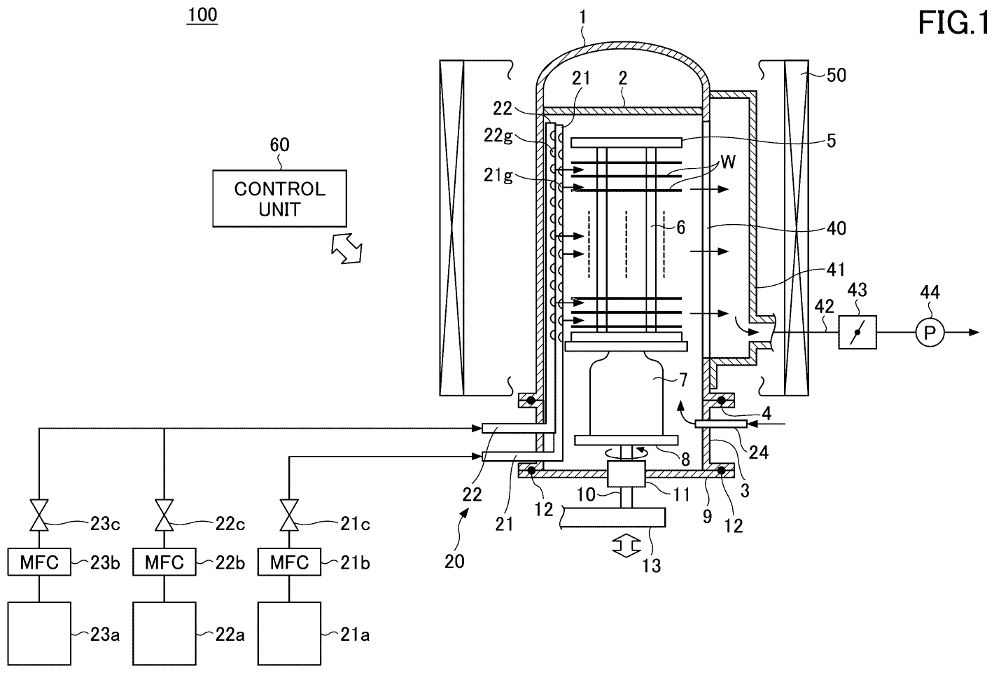

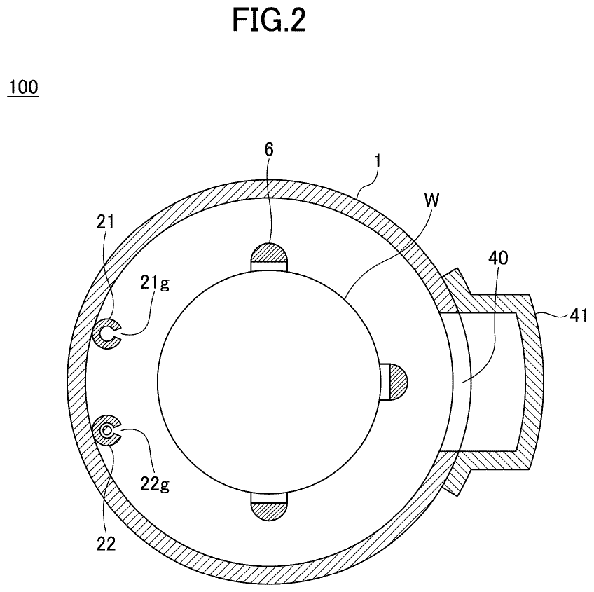

An example of a substrate processing apparatus 100 will be described with reference to FIGS. 1 and 2. FIG. 1 is a schematic diagram illustrating an example of the configuration of the substrate processing apparatus 100. FIG. 2 is a cross-sectional view of an example of the configuration of the substrate processing apparatus 100.

The substrate processing apparatus 100 has a cylindrical processing container 1 with a ceiling having an open lower end. The entire processing container 1 is formed of, for example, quartz. A ceiling plate 2 formed of quartz is provided near the upper end of the processing container 1, and a lower region of the ceiling plate 2 is sealed. A metallic manifold 3 formed in a cylindrical shape is connected to an opening at the lower end of the processing container 1 through a sealing member 4 such as an O-ring.

The manifold 3 supports the lower end of the processing container 1, and a wafer boat 5 (substrate support unit) is inserted into the processing container 1; on the wafer boat 5, many (e.g., 25 to 150) semiconductor wafers (hereinafter referred to as “substrates W”) are placed in multiple stages as substrates from the lower part the manifold 3. As described above, a large number of substrates W are housed in the processing container 1 substantially horizontally with intervals along the vertical direction. The wafer boat 5 is formed of, for example, quartz. The wafer boat 5 has three rods 6 (two are illustrated in FIG. 1), and a large number of substrates W are supported by grooves (not illustrated) formed in the rods 6.

The wafer boat 5 is mounted on a table 8 via a heat retaining cylinder 7 formed of quartz. The table 8 is supported on a rotary shaft 10 penetrating through a metal (stainless steel) lid 9 for opening and closing an opening at the lower end of the manifold 3.

The penetrating portion of the rotary shaft is provided with a magnetic fluid seal 11, which seals the rotary shaft 10 airtight and supports the rotary shaft 10 rotatably. A seal member 12 for maintaining airtightness in the processing container 1 is provided between the periphery of the lid 9 and the lower end of the manifold 3.

The rotary shaft 10 is attached to the tip of an arm 13 supported by a lifting mechanism (not illustrated) such as a boat elevator, and the wafer boat 5 and the lid 9 are lifted and lowered integrally, and are inserted into and removed from the processing container 1. The table 8 may be fixed to the side of the lid 9, and the substrate W may be processed without rotating the wafer boat 5.

The substrate processing apparatus 100 has a gas supplying unit 20 for supplying predetermined gases such as processing gas and purge gas into the processing container 1.

The gas supplying unit 20 has gas supply pipes (injectors) 21, 22, and 24. The gas supply pipes 21 and 22 are formed of quartz, for example, and extend vertically by being bent upward and penetrating inward through the side wall of the manifold 3. In the vertical portions of the gas supply pipes 21 and 22, a plurality of gas holes 21g and 22g are formed at predetermined intervals over a length in the vertical direction corresponding to the wafer support range of the wafer boat 5. The gas holes 21g and 22g discharge gas in the horizontal direction. The gas supply pipe 24 is formed of quartz, for example, and is formed of a short quartz pipe provided to penetrate through the side wall of the manifold 3.

The vertical portion (the vertical portion where the gas holes 21g are formed) of the gas supply pipe 21 is provided in the processing container 1. The first gas is supplied to the gas supply pipe 21 from a gas supply source 21a via a gas pipe. The gas pipe is provided with a flow controller 21b and an opening/closing valve 21c. Thus, the first gas from the gas supply source 21a is supplied into the processing container 1 via the gas pipe and the gas supply pipe 21 by a side flow.

The gas supply source 21a supplies the first gas. Here, the first gas supplies a silicon precursor gas containing silanol. As the silicon precursor gas, for example, TPSOL gas, triethylsilanol, methyl bis (tert-pentoxy) silanol, and tris (tert-butoxy) silanol may be used. In the following description, it is assumed that the first gas is TPSOL (tris (tert-pentoxy) silanol) gas.

The vertical portion of the gas supply pipe 22 (the vertical portion where the gas holes 22g are formed) is provided in the processing container 1. The second gas is supplied to the gas supply pipe 22 from the gas supply source 22a through a gas pipe. The gas pipe is provided with a flow controller 22b and an opening/closing valve 22c. Thus, the second gas from the gas supply source 22a is supplied into the processing container 1 via the gas pipe and the gas supply pipe 22 by a side flow.

The gas supply source 22a supplies the second gas. Here, the second gas supplies the metal-containing catalyst gas that forms a single molecular layer of the metal catalyst on the surface of the substrate W. The metal-containing catalyst gas includes a gas of a metal, a semimetal, or a compound thereof having Lewis acid characteristics.

Specifically, the metal-containing catalyst gas can be an organic, inorganic, halide precursor gas containing, for example, Al, Co, Hf, Ni, Pt, Ru, W, Zr, Ti, B, Ga, In, Zn, Mg, and Ta. The metal catalyst may be a backing in which Al, Co, Hf, Ni, Pt, Ru, W, Zr, Ti, B, Ga, In, Zn, Mg, and Ta are exposed. In the following description, it is assumed that the second gas is TMA (trimethylaluminum) gas.

Dilution gas (additional purge gas) is supplied to the gas supply pipe 22 from the gas supply source 23a via a gas pipe. The gas pipe is provided with a flow controller 23b and an opening/closing valve 23c. Thereby, the dilution gas from the gas supply source 23a is supplied into the processing container 1 via the gas pipe and the gas supply pipe 22 by a side flow.

Here, the gas supply source 23a supplies the dilution gas. As the dilution gas, for example, an inert gas such as argon (Ar) or nitrogen (N₂) can be used. In the following description, the dilution gas will be described as N₂ gas.

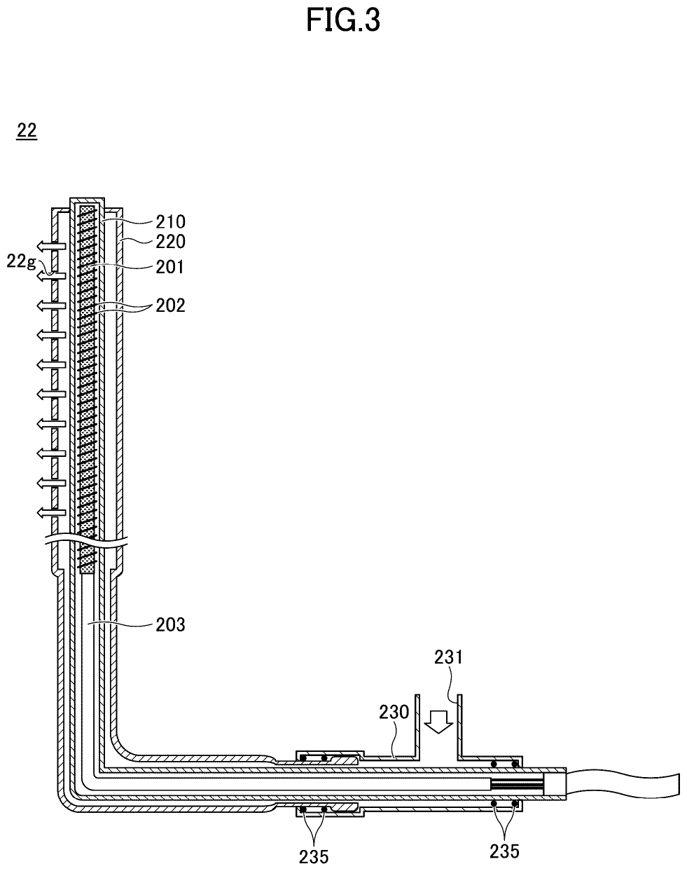

Here, the gas supply pipe 22 will be described further with reference to FIG. 3. FIG. 3 is a cross-sectional view illustrating an example of the gas supply pipe 22.

The gas supply pipe 22 has an inner pipe 210, an outer pipe 220, and an adapter 230. The outer pipe 220 and the adapter 230 are connected through a seal 235. An inner pipe 210 is arranged inside the outer pipe 220 and the adapter 230. Inside the inner pipe 210, an alumina core 201, a heating element 202, and a flexible cable 203 are included. The heating element 202 is wound around the alumina core 201. The flexible cable 203 connects the heating element 202 to the heater power supply (not illustrated). By supplying power from the heater power supply to the heating element 202 through the flexible cable 203, the heating element 202 generates heat and the alumina core 201 is heated.

The gas supplied from the supply port 231 of the adapter 230 passes through the space between the inner pipe 210 and the adapter 230 and the space between the inner pipe 210 and the outer pipe 220, and is discharged from the gas holes 22g. By supplying electric power to the heating element 202 from the heater power source, the gas is heated, and the heated gas is discharged from the gas holes 22g. As described above, the gas supply pipe 22 has an outer pipe 220 through which gas flows, and a gas heating unit arranged in the outer pipe 220 to heat the gas flowing through the outer pipe 220. The gas heating unit includes the core 201 and the heating element 202. The gas heating unit is arranged in the outer pipe 220 arranged in the processing container 1.

Returning to FIG. 1, purge gas is supplied to the gas supply pipe 24 from a purge gas supply source (not illustrated) via a gas pipe. The gas pipe (not illustrated) is provided with a flow controller (not illustrated) and an opening/closing valve (not illustrated). As a result, the purge gas from the purge gas supply source is supplied into the processing container 1 through the gas pipe and the gas supply pipe 24. For example, an inert gas such as argon (Ar) or nitrogen (N₂) can be used as the purge gas. Although the case where the purge gas is supplied from the purge gas supply source to the processing container 1 through the gas pipe and the gas supply pipe 24 has been described, the embodiment is not limited thereto, and the purge gas may be supplied from any of the gas supply pipes 21 to 23.

An exhaust port 40 for vacuum-exhausting the inside of the processing container 1 is provided on a side wall part of the processing container 1. The exhaust port 40 is formed elongated vertically corresponding to the wafer boat 5. An exhaust port cover member 41 formed to have a U-shape cross section to cover the exhaust port 40 is attached to a portion of the processing container 1 corresponding to the exhaust port 40. The exhaust port cover member 41 extends upward along the side wall of the processing container 1. An exhaust pipe 42 for exhausting the air from the processing container 1 through the exhaust port 40 is connected to the lower part of the exhaust port cover member 41. An exhaust device 44 including a pressure control valve 43 and a vacuum pump for controlling the pressure in the processing container 1 is connected to the exhaust pipe 42, and the air inside the processing container 1 is exhausted through the exhaust pipe 42 by the exhaust device 44.

A cylindrical heating mechanism 50 for heating the processing container 1 and the substrate W inside the processing container 1 is provided so as to surround the outer periphery of the processing container 1.

The substrate processing apparatus 100 has a control unit 60 (controller). The control unit 60 controls, for example, the operation of each part of the substrate processing apparatus 100, for example, the supplying/stopping of each type of gas by opening/closing the opening/closing valves 21c to 23c, controls the gas flow rate by the flow controllers 21b to 23b, and controls the exhaust by the exhaust device 44. The control unit 60 also controls, for example, the on-off control of the high-frequency power by a high-frequency power supply 35, and the temperature of the substrate W by the heating mechanism 50.

The control unit 60 may be, for example, a computer. Further, the computer program for performing the operation of each unit of the substrate processing apparatus 100 is stored in a storage medium. The storage medium may be, for example, a flexible disk, a compact disk, a hard disk, a flash memory, a DVD, or the like.

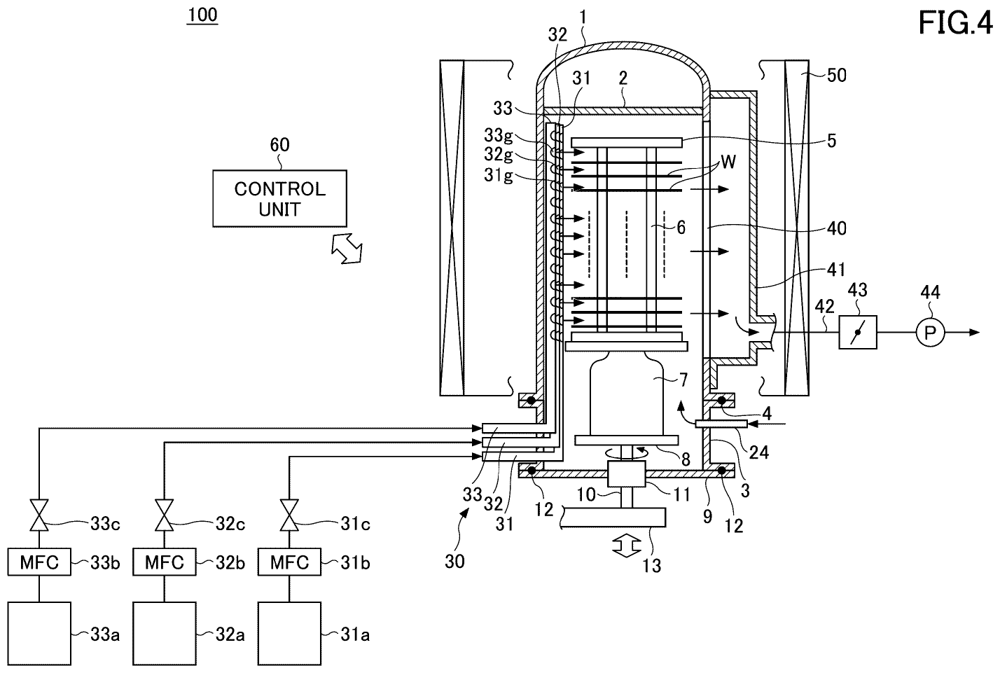

Another example of the substrate processing apparatus 100 will be described with reference to FIG. 4. FIG. 4 is a schematic diagram illustrating another example of the configuration of the substrate processing apparatus 100. With respect to configurations overlapping with those of the substrate processing apparatus 100 illustrated in FIG. 1, overlapping descriptions will be omitted.

The substrate processing apparatus 100 illustrated in FIG. 1 has the gas supplying unit 20. The gas supplying unit 20 has the gas supply pipes 21, 22, and 24. The gas supply pipe 21 is supplied with gas from the gas supply source 21a, and the gas supply pipe 22 is supplied with gas from the gas supply source 22a and the gas supply source 23a.

On the other hand, in the substrate processing apparatus 100 illustrated in FIG. 4, gas supply pipes 31 to 33 are provided for the gas supply sources 21a to 23a, respectively. Specifically, in the substrate processing apparatus 100 illustrated in FIG. 4, the gas supply unit 30 is provided. The gas supply unit 30 includes the gas supply pipes (injectors) 31, 32, 33, and 24. The gas supply pipes 31, 32, and 33 are formed of quartz, for example, and extend vertically by being bent upward and penetrating through the side wall of the manifold 3 toward the inside. In the vertical portions of the gas supply pipes 31, 32, and 33, a plurality of gas holes 31g, 32g, and 33g are formed at predetermined intervals over a length in the vertical direction corresponding to the wafer support range of the wafer boat 5. The gas holes 31g, 32g, and 33g discharge gas in the horizontal direction. The gas supply pipe 24 is formed of quartz, for example, and consists of a short quartz pipe provided by penetrating through the side wall of the manifold 3.

The vertical portion (the vertical portion where the gas holes 31g are formed) of the gas supply pipe 31 is provided in the processing container 1. The first gas is supplied to the gas supply pipe 31 from the gas supply source 21a via the gas pipe. The gas pipe is provided with the flow controller 21b and the opening/closing valve 21c. Thereby, the first gas from the gas supply source 21a is supplied into the processing container 1 via the gas pipe and the gas supply pipe 31 by a side flow.

The vertical portion (the vertical portion where the gas holes 32g are formed) of the gas supply pipe 32 is provided in the processing container 1. The second gas is supplied to the gas supply pipe 32 from the gas supply source 22a through the gas pipe. The gas pipe is provided with the flow controller 22b and the opening/closing valve 22c. As a result, the second gas from the gas supply source 22a is supplied into the processing container 1 via the gas pipe and the gas supply pipe 22 by a side flow.

The vertical portion of the gas supply pipe 33 (the vertical portion where the gas holes 33g are formed) is provided in the processing container 1. Dilution gas is supplied to the gas supply pipe 33 from the gas supply source 23a through the gas pipe. The gas pipe is provided with the flow controller 23b and the opening/closing valve 23c. Thereby, the dilution gas from the gas supply source 23a is supplied into the processing container 1 via the gas pipe and the gas supply pipe 33 by a side flow.

The gas supply pipe 33, similar to the gas supply pipe 32 illustrated in FIG. 3, has a double pipe structure and is configured to heat the gas.

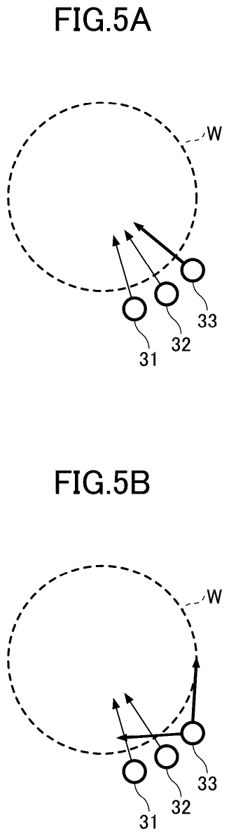

FIGS. 5A and 5B are schematic diagrams illustrating an example of a gas discharge direction. As illustrated in FIG. 5A, the gas supply pipes 31 to 33 may be configured to discharge gas toward the center of the substrate W. As illustrated in FIG. 5B, the gas supply pipes 31 and 32 may be configured to discharge gas toward the center of the substrate W, and the gas supply pipe 33 may be configured to discharge gas toward the outer periphery of the substrate W.

### <Film Forming Process According to the First Embodiment>

Next, an example of the film forming process by the substrate processing apparatus 100 will be described. Here, a case in which a SiO₂ film is formed on the substrate W will be described. The case in which the substrate processing apparatus 100 illustrated in FIG. 1 is used will be described by way of example, but the substrate processing apparatus 100 illustrated in FIG. 4 may be used.

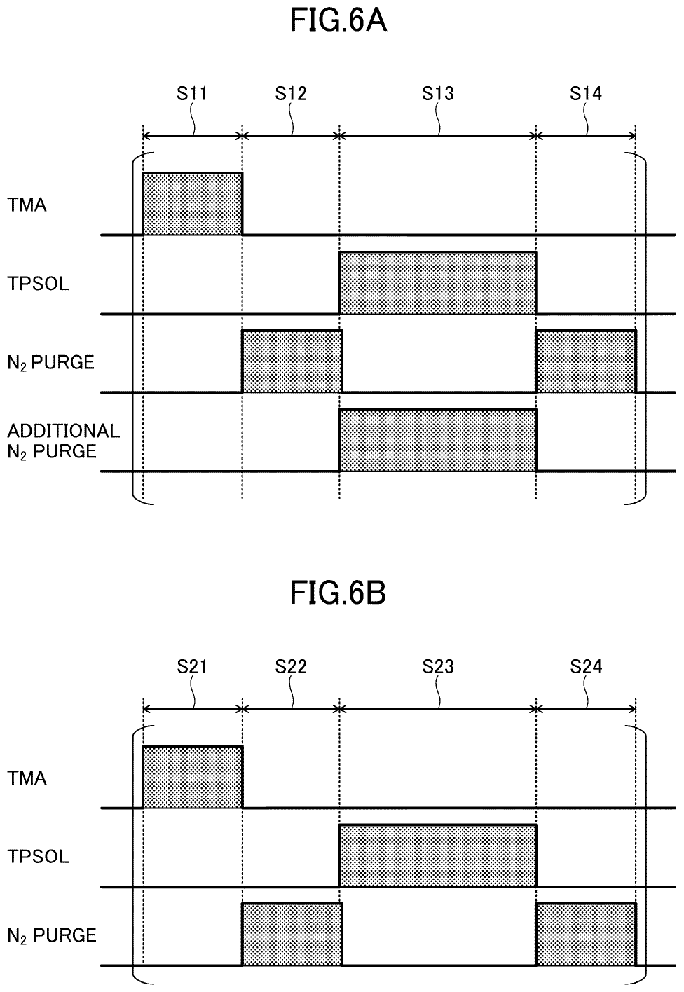

FIG. 6A is a time chart illustrating an example of a film forming process according to the first embodiment. The film forming process according to the first embodiment is a process of forming a SiO₂ film on a substrate W by repeating a predetermined cycle of step S11 for supplying a metal-containing catalyst gas (TMA gas), step S12 for purging, step S13 for supplying a silicon precursor gas (TPSOL gas) and a heated dilution gas, and step S14 for purging as one cycle. In FIG. 6A, one cycle is illustrated in parentheses. In steps S11 to S14, N₂ gas, which is the purge gas, may be constantly (continuously) supplied from the gas supply pipe 24 during the film forming process.

Here, the substrate W in the processing container 1 is heated to a predetermined temperature (for example, 100° C. to 400° C.) by the heating mechanism 50.

Step S11 of supplying the metal-containing catalyst gas is a step of supplying the metal-containing catalyst gas (TMA gas) into the processing container 1. In step S11, the control unit 60 supplies the metal-containing catalyst gas into the processing container 1 from the gas supply source 22a through the gas supply pipe 22 by opening the opening/closing valve 22c. As a result, the metal-containing catalyst gas is adsorbed on the surface of the substrate W to form a single molecular layer of the metal catalyst. Here, the adsorption of the TMA gas on the substrate surface is saturated.

The purging step S12 is a step of purging excess metal-containing catalyst gas or the like in the processing container 1. In step S12, the control unit 60 closes the opening/closing valve 22c to stop the supply of metal-containing catalyst gas. The control unit 60 also supplies purge gas from the gas supply pipe 24 into the processing container 1 (N₂ purge). This purges excess metal-containing catalyst gas and the like in the processing container 1.

Step S13 of supplying silicon precursor gas is a step of supplying silicon precursor gas (TPSOL gas) into the processing container 1. In step S13, the control unit 60 supplies silicon precursor gas from the gas supply source 21a through the gas supply pipe 21 into the processing container 1 by opening the opening/closing valve 21c. In addition, the control unit 60 heats the gas by energizing the heating element 202, and opens the opening/closing valve 23c to supply the heated side flow dilution gas (additional N₂ purge) from the gas supply source 23a through the gas supply pipe 22 into the processing container 1. The temperature of the dilution gas is heated to a temperature (for example, 100° C. to 600° C.) that is higher than the temperature of the substrate W. Thus, the SiO₂ film is formed by reacting with the metal catalyst on the surface of the substrate W. The formation of the SiO₂ film is a supply rate-determined state in which the film formation is determined by the supply rate of TPSOL gas.

The purging step S14 is a step of purging excess silicon precursor gas or the like in the processing container 1. In step S14, the control unit 60 closes the opening/closing valve 22c and stops the supply of silicon precursor gas. The control unit 60 also closes the opening/closing valve 23c and stops the supply of purge gas in the side flow. The control unit 60 also supplies purge gas from the gas supply pipe 24 into the processing container 1 (N₂ purge). As a result, excess silicon precursor gas and the like in the processing container 1 is purged.

By repeating the above cycle, a SiO₂ film having a desired thickness is formed on the substrate W.

FIG. 6B is a time chart illustrating an example of a film forming process according to a first reference example. The film forming process according to the first reference example is a process of forming a SiO₂ film on a substrate W by repeating a predetermined cycle of step S21 for supplying a metal-containing catalyst gas (TMA gas), step S22 for purging, step S23 for supplying a silicon precursor gas (TPSOL gas), and step S24 for purging, as one cycle. The step S23 differs in that the heated purge gas is not supplied into the processing container 1. Other configurations are the same as above, and overlapping explanations will be omitted.

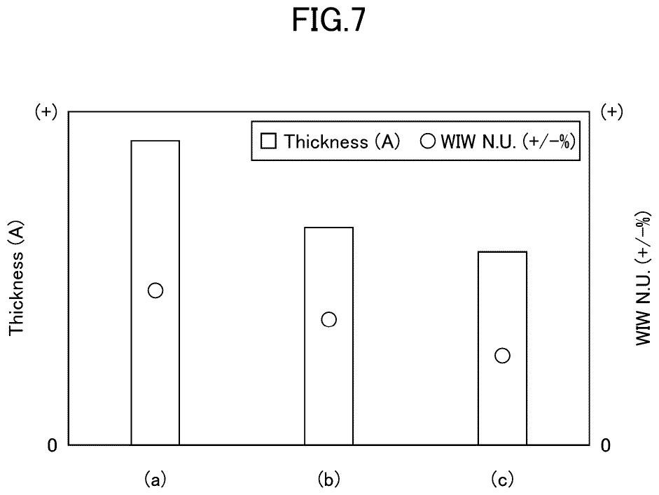

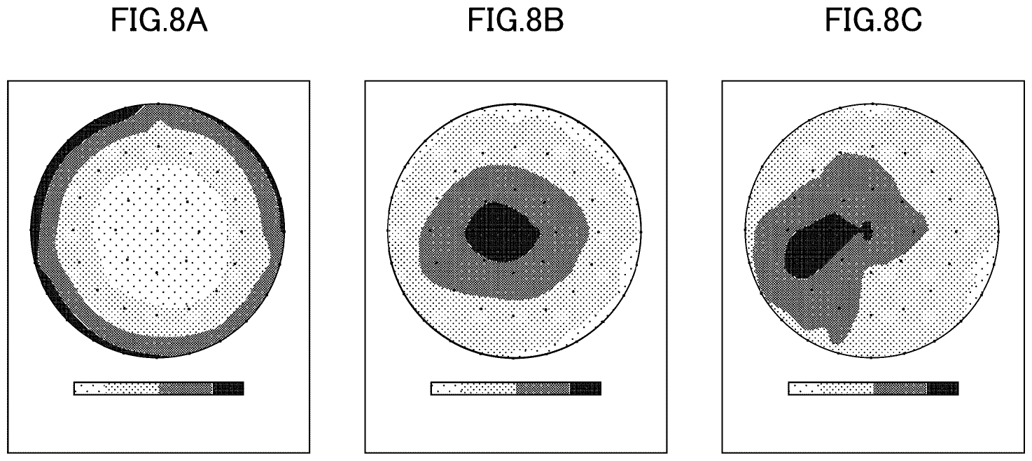

FIG. 7 is an example of a graph illustrating film thickness and in-plane uniformity. FIGS. 8A to 8C are examples of diagrams illustrating film thickness distribution. In FIG. 7, the average thickness corresponding to the left vertical axis is illustrated as a bar graph, and the in-plane uniformity (WIW N. U.) corresponding to the right vertical axis is illustrated as a circle. In FIGS. 8A to 8C, the thicker the film, the finer (darker) the illustrated dot pattern, and the thinner the film, the coarser (thinner) the illustrated dot pattern. FIG. 8A illustrates a configuration in which the side flow purge gas is not supplied when the TPSOL is supplied (see FIG. 6B). FIG. 8B illustrates a configuration in which the side flow purge gas is supplied when the TPSOL is supplied (see FIG. 6A). FIG. 8C illustrates a configuration in which the heated side flow purge gas is supplied when the TPSOL is supplied (see FIG. 6A).

As illustrated in FIG. 7, by comparing (a) with (b) and (c), the average film thickness decreases when N₂ gas is supplied in the side flow from the gas supply pipe 22 different from the gas supply pipe 21 for supplying the TPSOL, when supplying the TPSOL.

On the other hand, as illustrated in FIGS. 8A to 8C, in the in-plane distribution of the film thickness in FIG. 8A, the outer periphery is higher than the inner periphery (recessed state). In contrast, in FIGS. 8B and 8C, the in-plane distribution of the film thickness in the inner periphery is higher than the outer periphery (protruding state). As illustrated in FIGS. 7 and 8A to 8C, in FIG. 8C, the in-plane uniformity is further improved by supplying the heated purge gas by side flow.

Here, with respect to the temperature dependence of the film thickness of TPSOL, the GPC (film formation amount per cycle) is approximately constant at a low GPC in a temperature range of 150° C. or less, the GPC increases at a temperature range of around 200° C., and the GPC stabilizes at a low GPC in a temperature range of 250° C. or more. At a temperature range of around 200° C., if the supplying time of TPSOL is extended, the film thickness increases, thereby having a tendency of being determined by the supply rate.

For example, when the temperature in the processing container 1 heated by the heating mechanism 50 is set to 200° C. and a high temperature (e.g., 400° C.) dilution gas is supplied in the side flow, TPSOL is diluted by the dilution gas at the outer periphery of the substrate W, and the temperature at the outer periphery of the substrate W becomes a temperature range where the GPC of TPSOL is low (e.g., 250° C. or higher), thereby reducing the film formation rate. On the other hand, at the central portion of the substrate W, the GPC of TPSOL becomes a high temperature range (e.g., around 200° C.), and the film formation rate of the SiO₂ film becomes higher than that at the outer periphery. Thus, the in-plane distribution of the film thickness can be controlled so that the inner periphery becomes a higher state than the outer periphery (protruding state).

Thus, in the film forming process according to the first embodiment, when the first gas (TPSOL gas) and the second gas (TMA gas) are alternately supplied to form a film on the substrate W, when the first gas is supplied into the processing container 1 from the gas supply pipe 21, the purge gas heated to be above the temperature of the substrate W is supplied by a side flow into the processing container 1 from the gas supply pipe 22 different from the gas supply pipe 21. Thus, the in-plane distribution of the film thickness can be adjusted.

The film thickness can be controlled without using plasma treatment, and, therefore, it is possible to prevent the influence of plasma on the underlying film of the substrate W or the like.

Further, the temperature of the surface of the substrate W when the first gas (TPSOL gas) is supplied can be made higher than the temperature of the surface of the substrate W when the second gas (TMA gas) is supplied. Here, the temperature range in which the first gas preferably reacts with the catalyst on the surface of the substrate W is higher than the temperature range in which the second gas is preferably adsorbed on the surface of the substrate W. The temperature of the substrate W can be increased to accelerate the reaction of the first gas by supplying the heated purge gas in the side flow when supplying the first gas.

The in-plane distribution of the film thickness of the substrate W can be controlled by controlling the temperature and flow rate of the dilution gas.

When the TMA gas is supplied, the gas heating unit may also be operated to supply the heated TMA gas to the processing container 1. Thus, the temperature of the TMA gas on the surface of the substrate W is controlled.

In the substrate processing apparatus 100 illustrated in FIG. 4, when the TMA gas is supplied from the gas supply pipe 31, the heated dilution gas from the gas supply pipe 33 may be supplied. Thereby, the temperature distribution and the concentration distribution of the TMA gas on the surface of the substrate W are controlled.

Although the gas supply pipe 22 has been described as having a gas heating unit (the alumina core 201, the heating element 202), the configuration of the substrate processing apparatus 100 is not limited to this. The gas supply pipe 22 may have a gas cooling unit for cooling the gas. That is, the dilution gas adjusted in temperature may be supplied from the gas supply pipe 22 to the processing container 1.

For example, by setting the temperature in the processing container 1 heated by the heating mechanism 50 to 200° C. and supplying the dilution gas at a lower temperature (e.g., 100° C.) than the substrate W in the side flow, the TPSOL is diluted by the dilution gas in the outer peripheral portion of the substrate W, and the temperature in the outer peripheral portion of the substrate W becomes a temperature range where the GPC of the TPSOL is lower (e.g., 150° C. or lower), thereby reducing the film formation rate. On the other hand, in the central portion of the substrate W, the GPC of the TPSOL becomes a high temperature range (e.g., around 200° C.), and the film formation rate of the SiO₂ film becomes higher than that in the outer peripheral portion. Thus, it is possible to control the in-plane distribution of the film thickness so that the inner peripheral portion is in a higher state (protruding state) than the outer peripheral portion.

### <Film Forming Process According to the Second Embodiment>

Next, an example of the film forming process by the substrate processing apparatus 100 will be described. Here, an example in which an AlO film is formed on the substrate W will be described. The example in which the substrate processing apparatus 100 illustrated in FIG. 1 is used will be described, but the substrate processing apparatus 100 illustrated in FIG. 4 may be used. Here, the gas supply source 21a supplies an oxidizing gas (O₃ gas)) as a first gas, the gas supply source 22a supplies a metal-containing gas (TMA gas) as a second gas, and the gas supply source 23a supplies an inert gas (N₂ gas) as a dilution gas.

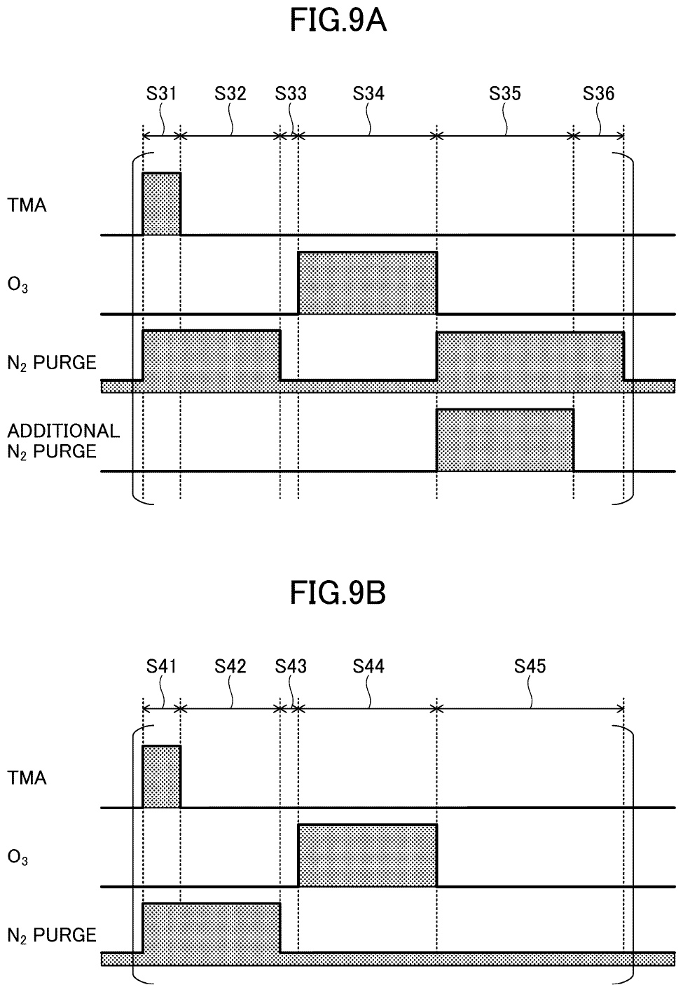

FIG. 9A is a time chart illustrating an example of a film forming process according to the second embodiment. The film forming process according to the second embodiment is a process of forming an AlO film on a substrate W by repeating a predetermined cycle of step S31 for supplying a metal-containing gas (TMA gas), steps S32 and S33 for purging, step S34 for supplying an oxide gas (O₃ gas)), and steps S35 and S36 for purging, as one cycle. In FIG. 9A, one cycle is illustrated in parentheses. In steps S31 to S36, N₂ gas, which is the purge gas, may be constantly (continuously) supplied from the gas supply pipe 24 during the film forming process.

Here, the substrate W in the processing container 1 is heated to a predetermined temperature (for example, 100° C. to 550° C.) by the heating mechanism 50.

Step S31 of supplying the metal-containing gas is a step of supplying the metal-containing gas (TMA gas) into the processing container 1. In step S31, the control unit 60 supplies the metal-containing gas from the gas supply source 22a through the gas supply pipe 22 into the processing container 1 by opening the opening/closing valve 22c. The control unit 60 supplies the purge gas from the gas supply pipe 24 into the processing container 1 (N₂ purge). As a result, the metal-containing gas is adsorbed on the surface of the substrate W.

Steps S32 and S33 for purging are steps for purging excess metal-containing gas or the like in the processing container 1. In step S32, the control unit 60 closes the opening/closing valve 22c to stop the supply of metal-containing gas. The control unit 60 also supplies purge gas from the gas supply pipe 24 into the processing container 1 (N₂ purge). A large flow of purge gas is supplied in step S32, and a small flow of purge gas is supplied in the subsequent step S33. As a result, excess metal-containing gas or the like in the processing container 1 is purged.

Step S34 of supplying the oxidizing gas is a step of supplying the oxidizing gas (O₃ gas)) into the processing container 1. In step S34, the control unit 60 supplies the oxidizing gas from the gas supply source 21a through the gas supply pipe 21 into the processing container 1 by opening the opening/closing valve 21c. Thus, the AlO film is formed by reacting with the metal-containing gas on the surface of the substrate W. In this case, a reaction by-product (H₂O) is also formed.

Steps S35 and S36 for purging are steps for purging excess oxide gas or the like in the processing container 1. In step S35, the control unit 60 closes the opening/closing valve 22c to stop the supply of the oxide gas. The control unit 60 also supplies the purge gas from the gas supply pipe 24 into the processing container 1 (N₂ purge). Further, the control unit 60 supplies the heated dilution gas (additional N₂ purge) of the side flow from the gas supply source 23a through the gas supply pipe 22 into the processing container 1 by energizing the heating element 202 to heat the gas and opening the opening/closing valve 23c. The temperature of the dilution gas is heated to a temperature higher than the temperature of the substrate W (for example, 150° C. to 600° C.). In step S36, the control unit 60 closes the opening/closing valve 23c and stops the supply of the dilution gas. The control unit 60 also supplies the purge gas from the gas supply pipe 24 into the processing container 1 (N₂ purge). A large flow of purge gas is supplied in step S35, and a small flow of purge gas is supplied in the subsequent step S36. As a result, excess oxidation gas and a reaction by-product (H₂O) in the processing container 1 are purged.

By repeating the above cycle, an AlO film having a desired film thickness is formed on the substrate W.

FIG. 9B is a time chart illustrating an example of a film forming process according to a second reference example. The film forming process according to the second reference example is a process of forming an AlO film on a substrate W by repeating a predetermined cycle of step S41 for supplying a metal-containing gas (TMA gas), steps S42 and S43 for purging, step S44 for supplying an oxide gas (O₃ gas)), and step S45 for purging, as one cycle. In step S45, the difference is that the heated purge gas is not supplied into the processing container 1. The other configurations are the same as above, and overlapping explanations are omitted.

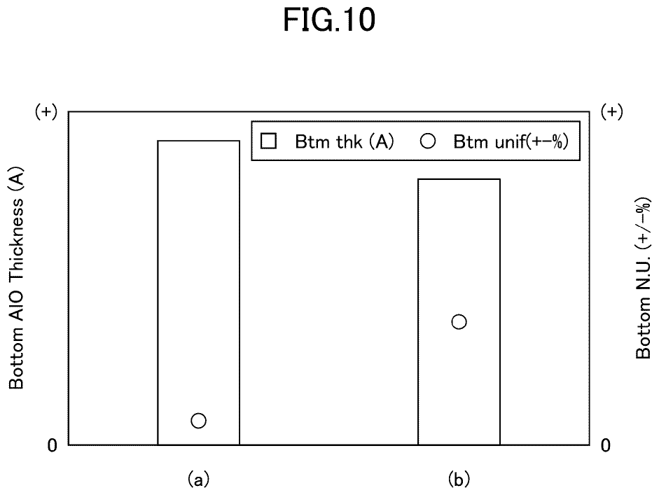

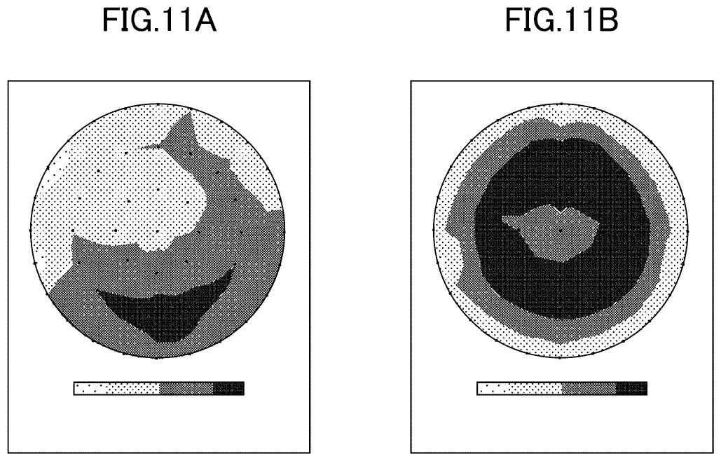

FIG. 10 is an example of a graph illustrating film thickness and in-plane uniformity. FIGS. 11A and 11B are examples of diagrams illustrating film thickness distribution. In FIG. 10, the average thickness corresponding to the left vertical axis is illustrated as a bar graph, and the in-plane uniformity (WIW N. U.) corresponding to the right vertical axis is illustrated as a circle. In FIGS. 11A and 11B, the thicker the film, the finer (darker) the illustrated dot pattern, and the thinner the film, the coarser (thinner) the illustrated dot pattern. Further, FIG. 11A illustrates a configuration in which the side flow purge gas is not supplied (see FIG. 9B). FIG. 11B illustrates a configuration in which the heated side flow purge gas is supplied (see FIG. 9A).

As illustrated in FIGS. 10, 11A, and 11B, the average film thickness and the in-plane distribution of the film thickness can be adjusted by supplying the heated dilution gas (N₂ gas) in the side flow in the purge step after the step in which the oxidizing gas is supplied.

Here, H₂O as a reaction by-product is heated by the heated dilution gas and removed from the surface of the substrate W. In the step of supplying the TMA gas in the next cycle, the reaction between TMA and H₂O is prevented.

The temperature of the substrate W can be increased before the TMA gas is supplied. Here, the temperature range in which the TMA gas preferably reacts with the surface of the substrate W is higher than the temperature range in which the O₃ gas) preferably reacts with the surface of the substrate W. By supplying, in the side flow, the purge gas heated before supplying the TMA gas, the temperature of the substrate W can be increased to promote the reaction of the TMA gas. Further, the thermal decomposition of the O₃ gas) can be prevented.

According to one aspect of the present invention, a film-forming method and a substrate processing apparatus for adjusting the in-plane distribution of the film thickness can be provided.

Although the film-forming method of the present embodiment (first and second embodiments) by the substrate processing apparatus 100 has been described above, the present disclosure is not limited to the above embodiments, etc., and various modifications and improvements can be made within the scope of the gist of the present disclosure described in the claims.

What is claimed is:

1. A film-forming method for forming a film on a substrate by switching gas to be supplied to the substrate in a processing container, the film-forming method comprising:
supplying, in the processing container, dilution gas that is heated to a temperature that is higher than a temperature of the substrate, from a second injector that is different from a first injector when supplying one kind of gas from the first injector into the processing container.

2. The film-forming method according to claim 1, further comprising:
supplying, in the processing container, the dilution gas that is heated from the second injector, when supplying first gas that reacts according to a supply rate from the first injector into the processing container.

3. The film-forming method according to claim 2, further comprising:
repeating a predetermined cycle in which one cycle includes
supplying the first gas from the first injector into the processing container and supplying the dilution gas that is heated from the second injector into the processing container, and
supplying second gas from the second injector into the processing container.

4. The film-forming method according to claim 3, wherein
the first gas is TPSOL (tris (tert-pentoxy) silanol), and
the second gas is TMA (trimethylaluminum).

5. The film-forming method according to claim 4, wherein
the temperature of the substrate is within a range of 100° C. to 400° C., and
the temperature of the dilution gas is within a range of 150° C. to 600° C.

6. The film-forming method according to claim 1, wherein the dilution gas is an inert gas.

7. The film-forming method according to claim 1, further comprising:
supplying, in the processing container, the dilution gas that is heated from the second injector, when supplying purge gas from the first injector into the processing container.

8. The film-forming method according to claim 7, further comprising:
repeating a predetermined cycle in which one cycle includes
supplying raw material gas into the processing container;
purging the raw material gas by supplying the purge gas into the processing container;
supplying reaction gas into the processing container; and
supplying the purge gas from the first injector into the processing container, supplying the dilution gas that is heated from the second injector into the processing container, and purging the reaction gas and a reaction by-product of the raw material gas and the reaction gas.

9. The film-forming method according to claim 8, wherein the reaction by-product includes H₂O.

10. The film-forming method according to claim 9, wherein
the raw material gas is TMA (trimethylaluminum), and
the reaction gas is 03.

11. The film-forming method according to claim 10, wherein
the temperature of the substrate is within a range of 100° C. to 550° C., and
the temperature of the dilution gas is within a range of 150° C. to 600° C.

12. The film-forming method according to claim 7, wherein the dilution gas is an inert gas.

13. A substrate processing apparatus comprising:
a processing container configured to house a substrate;
a first injector configured to supply a first gas into the processing container;
a second injector configured to supply a second gas or a dilution gas into the processing container;
a gas heater provided in the second injector; and
a controller, wherein
the substrate processing apparatus is configured to execute:
supplying the second gas from the second injector; and
supplying the first gas from the first injector and supplying the dilution gas that is heated to a temperature that is higher than a temperature of the substrate from the second injector.

14. The substrate processing apparatus according to claim 13, wherein
the second injector includes:
an outer pipe arranged inside the processing container; and
a gas heating unit arranged inside the outer pipe.
